(19) United States
(12) Patent Application Publication
(10) Pub. No.: US 2011/0260062 A1
(43) Pub. Date: Oct. 27, 2011

(54) INFRARED SENSOR AND INFRARED SENSOR MANUFACTURING METHOD

(75) Inventors: Kenjiro Fujimoto, Yamahashi (JP); Takanori Maeda, Saitama (JP); Takahiro Kawano, Aichi (JP)

(73) Assignee: PIONEER CORPORATION, Kanagawa (JP)

(21) Appl. No.: 13/141,604

(22) PCT Filed: Dec. 22, 2008
(86) PCT No.: PCT/JP2008/003887

§ 371 Date: Jul. 15, 2011

(51) Int. Cl. G01J 5/10; H01L 31/18

(52) U.S. Cl. 250/338.3; 250/338.1; 438/57; 257/E31.001

(57) ABSTRACT

An infrared ray sensor and a method of fabricating the same is provided to increase detection sensitivity and to be easily fabricated with high yield rate. Provided herein is an infrared ray sensor having a frame-shaped substrate section formed in a square frame shape, a projecting base material section formed inside the frame-shaped substrate section and elongating to an incident direction of an infrared ray, and an infrared ray detection section provided on at least an upper lateral surface of the projecting base material section. The projecting base material section is made up of a plurality of rib-like element base material sections having a plurality of vertical base material sections and horizontal base material sections combined in a lattice shape.

### BACKGROUND

1. Technical Field

The present invention relates to an infrared sensor such as a pyroelectric sensor, a thermopile, a bolometer in a MEMS (micro electro mechanical system) sensor and a method of fabricating the same.

2. Related Art

In recent years, as this kind of infrared ray sensor, there has been known an infrared ray detection apparatus in which a plurality of detection elements are arranged in matrix formation (see Patent Document 1). Each detection element has a light-receiving section arranged to suspend above a concave portion formed in a substrate and a beam supporting the light-receiving section on the substrate. The light-receiving section is disposed such that a light-receiving surface thereof is orthogonal to a light axis of an infrared ray, that is, the light-receiving surface is directed to a light axis direction of the infrared ray.
[Patent Document 1] JP-A-2007-333558

Thus, the known infrared ray sensor has a membrane structure in which a light-receiving area is made bigger and the light-receiving section is suspended from the substrate by the beam so as to restrain heat transfer from the light-receiving section to the substrate. Therefore, when the infrared ray sensor (detection element) is fabricated, it is necessary to provide a sacrifice layer or a deep trench, resulting in time consumption because of processing difficulty and in high cost.

### SUMMARY

It is an advantage of the invention to provide an infrared ray sensor which increases detection sensitivity and is easily fabricated with high yield rate, and a method of fabricating the same.

According to one aspect of the invention, there is provided an infrared sensor having a frame-shaped substrate section formed in a square frame shape, a projecting base material section formed inside the frame-shaped substrate section and elongating to an incident direction of an infrared ray, and an infrared ray detection section provided on at least an upper lateral surface of the projecting base material section. The projecting base material section is made up of a plurality of rib-like element base material sections combined in a net shape.

In this case, it is preferable that the plurality of element base material section includes a plurality of vertical base material sections and horizontal base material sections, and that the projecting base material section be made up of the plurality of vertical base material sections and horizontal base material sections combined in a lattice shape.

According to this configuration, since the projecting base material section having the infrared ray detection section elongates to an incident direction of an infrared ray, this portion can be easily formed by etching (deep etching) or the like. Further, since the infrared ray detection section is provided on at least an upper lateral surface of the projecting base material section, the infrared ray can be received sufficiently. Still further, it is possible to restrain a heat release path, resulting in suppression of heat transfer from the infrared ray detection section. Since the projecting base material section is made up of the plurality of rib-like element base material sections in the net shape (lattice shape), even if the element base material sections are thin, the projecting base material section has strength overall.

Also, it is preferable that the projecting base material section be disposed inside the frame-like substrate section having space therebetween and further have a beam section which supports the projecting base material section on the frame-like substrate section.

In this case, it is preferable that the beam section be made up of a plurality of beam-like or bar-like connection sections provided between the projecting base material section and the frame-like substrate section.

With this configuration, since the projecting base material section can be kept in separation from the frame-like substrate section, it is possible to restrain heat received at the infrared ray detection section from transferring (heat transfer) to the substrate sufficiently. Further, thermal cross talk between adjacent infrared ray sensors can be prevented. It is preferable that the beam-like connection sections have identical height with the projecting base material section. Further, it is preferable that the bar-like connection sections be connected to upper ends or lower ends of the projecting base material section.

It is preferable that a base substrate section be further provided which covers between bottom ends of the frame-like substrate section and which is disposed spaced apart from the projecting base material section.

With this configuration, it is not only possible to restrain heat received at the infrared ray detection section from transferring (heat transfer) to the substrate sufficiently, but also possible to absorb the infrared ray reflected from the base substrate section in the infrared ray detection section. Further, rigidness of the frame-like substrate section can be enhanced by the base substrate section.

Further, it is preferable that the frame-shaped substrate section and the projecting base material section be formed integrally with same material.

With this configuration, the frame-like substrate section and the projecting base material section can easily be formed from a substrate by etching or the like.

Also, it is preferable that length size of the projecting base material section to an elongation direction be larger than thickness size thereof.

With this configuration, heat capacity of the projecting base material section can be reduced by lengthen the projecting base material section and the heat transfer from the infrared ray detection section to the projecting base material section can be restrained.

Also, it is preferable that the projecting base material section be formed with heat insulation material or have a heat insulation layer on a surface thereof.

With this configuration, it is possible to restrain transfer of heat in the infrared ray detection section to the projecting base material section sufficiently.

Also, it is preferable that a surface of the infrared ray detection section be formed with an infrared ray absorption layer.

With this configuration, infrared ray absorptivity of the infrared ray detection section can be increased.

Also, it is preferable that the infrared ray detection section be laminated with an outer electrode layer, a pyroelectric layer and an inner electrode layer.

With this configuration, the infrared ray detection section can be made for forming in the projecting base material section.

A method of fabricating an infrared ray sensor of the invention is a method of fabricating the infrared ray sensor described above and has steps of etching by which a substrate is etched to pass through so as to form the frame-shaped substrate section and the projecting base material section in a net shape, and film forming which film-forms the infrared ray detection section on the projecting base material section after the etching.

With this configuration, the infrared ray sensor having high detection sensitivity can easily be fabricated with high yield rate.

Another method of fabricating the infrared ray sensor of the invention is a method of fabricating the infrared ray sensor described above and has steps of: preparing a laminated substrate which is laminated with a bottom substrate as the base substrate section, a sacrifice layer to be space between the projecting base material section and the base substrate section, and a top substrate as the frame-shaped substrate section; etching the laminated substrate in which the top substrate is penetrated to form the frame-shaped substrate section and the projecting base material section in a net shape; sacrifice layer etching to remove the sacrifice layer by etching after etching the laminated substrate; and film forming the infrared ray detection section on the projecting base material section after the sacrifice etching.

With this configuration, the infrared ray sensor having high detection sensitivity and high strength can be easily fabricated with high yield rate.

As described above, according to the invention, since the projecting base material section having the infrared ray detection section elongates to the incident direction of the infrared ray and the projecting base material section is disposed inside the frame-shaped substrate section, the infrared ray can be absorbed efficiently and the heat transfer from the infrared ray detection section can be restrained. Therefore, it is possible to enhance detection sensitivity and to fabricate easily with high yield rate.

### BRIEF DESCRIPTION OF THE DRAWINGS

FIG. 1 is a perspective view of an infrared ray sensor according to a first embodiment.

FIG. 2 is a cross sectional view of the infrared ray sensor according to the first embodiment.

FIG. 3 is a cross sectional view of the infrared ray sensor according to a modification.

FIG. 4 is a cross sectional view of the infrared ray sensor according to another modification.

FIG. 5 is an explanatory diagram explaining a method of fabricating the infrared ray sensor according to the first embodiment.

FIG. 6 is a perspective view of the infrared ray sensor according to a second embodiment.

FIG. 7 is a perspective view of the infrared ray sensor according to a third embodiment.

FIG. 8 is an explanatory diagram explaining a method of fabricating the infrared ray sensor according to the third embodiment.

### REFERENCE NUMERALS

1 infrared ray sensor
1A infrared ray sensor
1B infrared ray sensor
2 frame-shaped substrate section
3 projecting base material section
3A projecting base material section
3B projecting base material section
4 element base material section
4a vertical base material section
4b horizontal base material section
5 infrared ray detection section
5A infrared ray detection section
5B infrared ray detection section
6 beam section
6a beam-like connection section
6b bar-like connection section
7 base substrate section
11 heat insulation layer
13 inner electrode layer
14 pyroelectric layer
15 outer electrode layer
20 laminated substrate
21 bottom substrate
22 sacrifice layer
23 top substrate

### DESCRIPTION OF EXEMPLARY EMBODIMENTS

An infrared ray sensor and a method of fabricating the same according to one embodiment of the invention will be explained with reference to the accompanying drawings. The infrared ray sensor is a MEMS (micro electromechanical system) sensor fabricated by a microfabrication technique using silicon (wafer) or the like as material and is so-called a pyroelectric-type infrared ray sensor. The infrared ray sensor makes up a pixel (element) of an infrared detection apparatus manufactured in an array format.

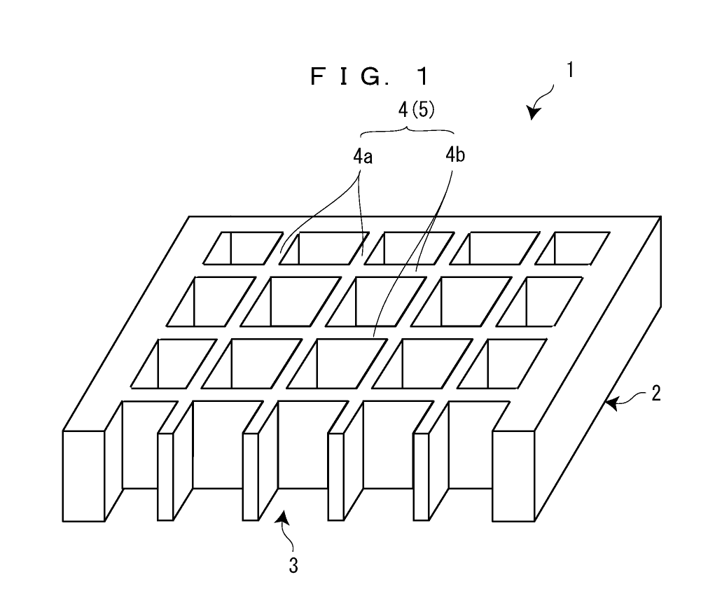

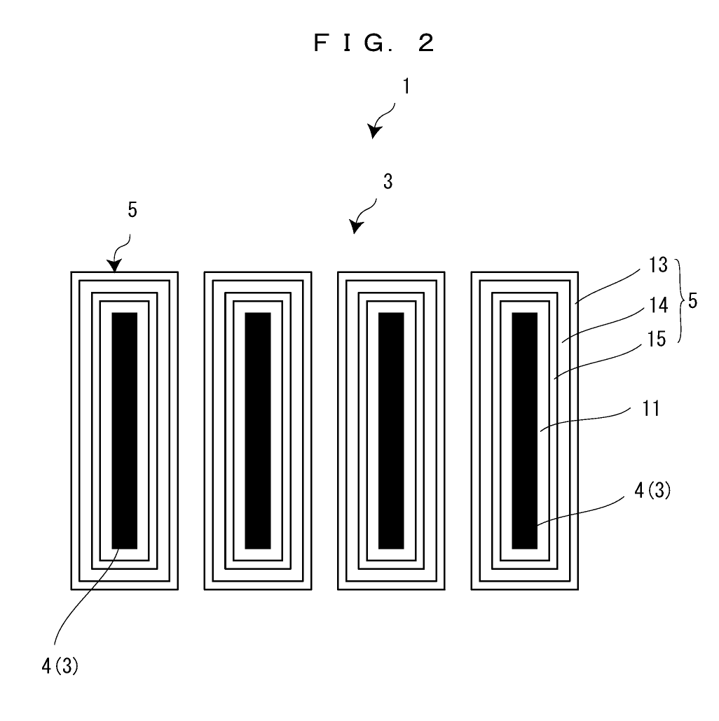

As shown in FIGS. 1 and 2, the infrared ray sensor 1 has a frame-shaped substrate section 2 formed in a square shape, a projecting base material section 3 formed inside the frame-shaped substrate section 2 and having a plurality of rib-like element base material sections 4 combined in a lattice shape, and an infrared ray detection section 5 provided to cover a surface of the projecting base material section 3. The frame-shaped substrate section 2 and the projecting base material section 3 are formed by etching by which a silicon substrate is penetrated. A plurality of vertical base material sections 4a and horizontal base material sections 4b forming a plurality of element base material sections 4 are formed as having identical height size and identical thickness. Further, the frame-shaped substrate section 2 and the projecting base material section 3 are formed as having identical height size.

Each element base material section (projecting base material section 3) 4 elongates to an incident direction of an infrared ray (a height direction in the figure) and is formed as thinner as possible. In other words, it is preferable that the thickness of the element base material section (projecting base material section 3) 4 be less than 1 μm. At least, the height size of the element base material section (projecting base material section 3) 4 is made larger than the thickness size thereof. Further, a heat insulation layer 11 (thermal insulation layer) is formed on a surface of the projecting base material section 3. The heat insulation layer 11 is formed by oxidizing thermally (SiO₂) the projecting base material section 3. In a case that the projecting base material section (element base material section 4) 3 is thinly formed, the projecting base material section 3 overall may be oxidized thermally. Also, a low thermally-conductive layer may be formed on the surface of the projecting base material section by forming a film with material having low heat conductivity.

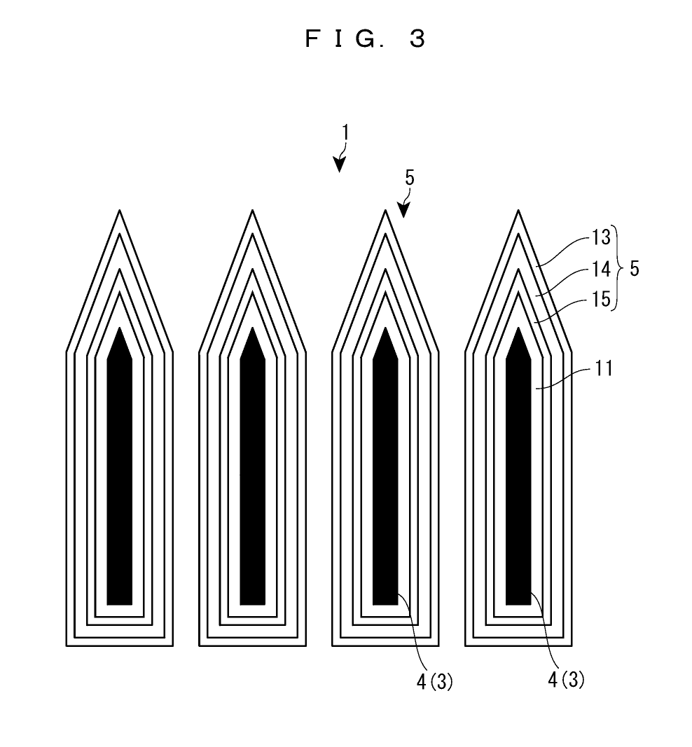

Though the projecting base material section 3 of the embodiment is formed with four vertical base material sections 4a and three horizontal base material sections 4b in the lattice shape, the number of base materials 4a and 4b is arbitrary. Mutual separation size and the height size of a plurality of element base material sections 4 is also arbitrary. Further, the element base material section 4 of the projecting base material section 3 may be formed in a honeycomb shape in place of the lattice shape. In other words, it is preferable that a plurality of element base material sections 4 be combined in a net shape in consideration of strength of the projecting base material section 3. Still further, a top portion of each element base material section (projecting base material section 3) 4 may be formed at a sharp angle (in respect of cross sectional direction) (see FIG. 3). By fabricating as such, it is possible to avoid reflection of the infrared ray from the top surface of the projecting base material section 3, that is, from the top surface of the infrared ray detection section 5, resulting in increasing infrared ray absorptivity of the infrared ray detection section 5.

As shown in FIG. 2, the infrared ray detection section 5 is formed by laminating with an inner electrode layer 13, a pyroelectric layer 14 and an outer electrode layer 15 in turn on the projecting base material section (element base material section 4) 3. Though it is preferable that the infrared ray detection section 5 be formed, in respect to the projecting base material section 3, only on the upper lateral surface thereof, the infrared ray detection section 5 is formed on the overall surface of the projecting base material section 3 in connection with a film formation process. The pyroelectric layer 14 is formed with, for example, PZT (Pb(Zr, Ti)O₃), SBT (SrBi₂Ta₂O₉), BIT (Bi₄Ti₃O₁₂), Lt (LiTaO₃), LN (LiNbO₃), BTO (BaTiO₃), BST (BaSrTiO₃), or the like. In this case, it is preferable that the pyroelectric layer 14 be formed with material having low dielectric constant in consideration of detection sensitivity, an upper portion of the infrared ray detection section 5 be highly crystallized by a post anneal process, and orientation of polarization be directed to C axis orientation with respect to the surface of the projecting base material section 3. By fabricating as such, it is possible to increase the detection sensitivity of the pyroelectric layer 14.

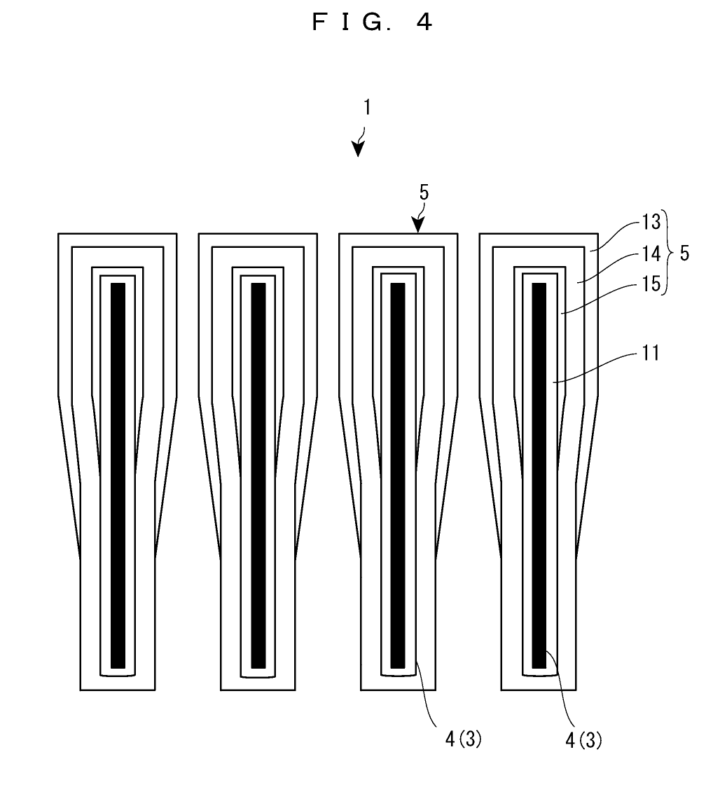

The inner electrode layer 13 is formed with, for example, SRO, Nb—STO, LNO (LaNiO₃) or the like. In this case, in consideration of film forming of the pyroelectric layer 14 on the inner electrode layer 13, it is preferable that the inner electrode layer 13 be formed with material of which crystal structure is identical as that of the pyroelectric layer 14. Further, the inner electrode layer 13 may be formed with generally used Pt, Ir, Ti, or the like. An infrared ray absorption layer (not shown) may be provided on a surface of the outer electrode layer 15 to enhance absorptivity for the infrared ray. In this case, the infrared ray absorption layer is formed with Au-Black or the like. As described above, the infrared ray detection section 5 may be formed only on the upper portion of the projecting base material section (element base material section 4) 5 (see FIG. 4). For example, the infrared ray detection section 5 is formed only on the upper portion of the projecting base material section 3 by film-forming the inner electrode layer 13, the pyroelectric layer 14 and the outer electrode layer 15 from skew while the frame-shaped substrate section 2 rotates.

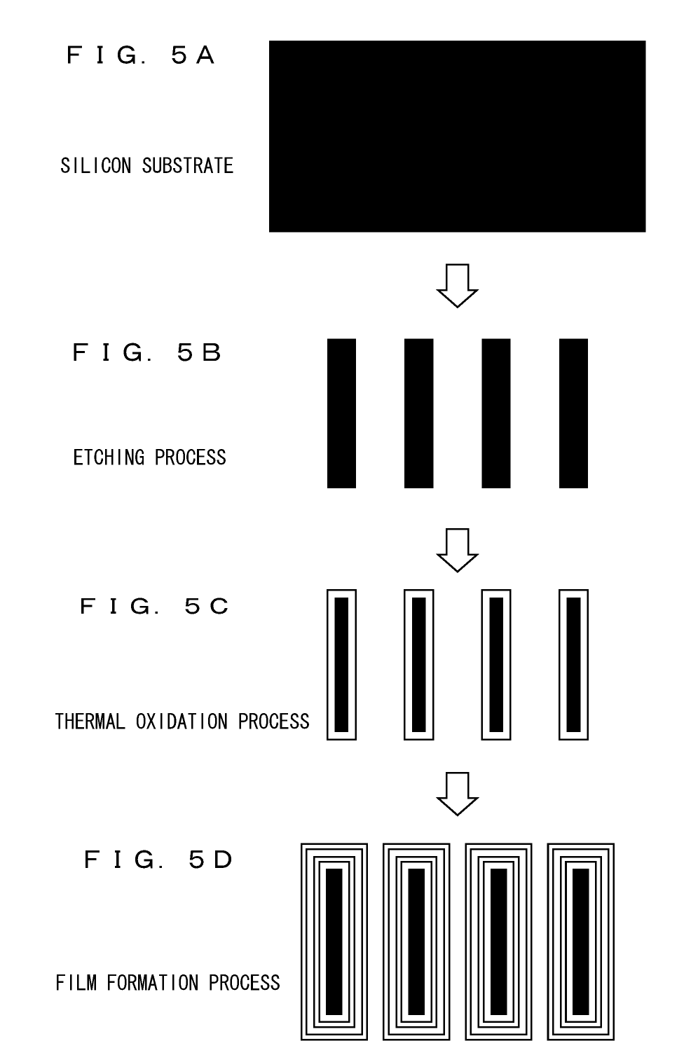

Referring to FIG. 5, a method of fabricating the infrared ray sensor 1 will be explained. The infrared ray sensor 1 of the embodiment is fabricated by the microfabrication technique of semiconductor using a silicon substrate (wafer). First of all, the silicon substrate coated with a resist by photolithography is etched to pass through (penetration etching: Deep RIE) so as to form the frame-shaped substrate section and the projecting base material section 3 in the lattice shape (etching process: FIG. 5A). Then, an oxidized film which is the heat insulation layer 11 is formed on the surface of the projecting base material section 3 by a thermal oxidation process (thermal oxidation process: FIG. 5B). Next, the infrared ray detection section 5 is film-formed with the inner electrode layer 13, the pyroelectric layer 14 and the outer electrode layer 15 in sequence on the surface of the projecting base material section 2 by, for example, epitaxial growth (CDV) (film formation process: FIG. 5C). In this epitaxial growth, it is preferable that buffer layers (not shown) are provided especially between the projecting base material sections 3 and the inner electrode layers 13 respectively to achieve high quality film formation. The buffer layers are preferably formed with, for example, YSZ, CeO₂, Al₂O₂, and STO.

After the film formation process, a polarization process may be performed in which high voltage is applied between the inner electrode layer 13 and the outer electrode layer 15, and crystal of the pyroelectric layer 14 is directed perpendicular to the surface of the projecting base material section 3. More simply, the upper portion of the infrared ray detection section 5 may be post-annealed to promote crystallization of the pyroelectric layer 14. Thus, the detection sensitivity of the infrared ray detection section 5 can be increased.

With such a structure, since the projecting base material section 3 having the infrared ray detection section 5 elongates to the incident direction of the infrared ray, this portion can be easily formed by etching (penetration etching). Further, since the infrared ray detection section 5 is provided on the projecting base material section 3 overall, the infrared ray can be received sufficiently. Still further, it is possible to restrain volume of the projecting base material section 3, that is, a heat transfer path, leading to suppression of heat transfer from the infrared ray detection section 5. Furthermore, since the projecting base material section 3 is structured by combination of a plurality of rib-like element base material sections 4 in the net shape (lattice shape), even if the element base material sections 4 are thin, it is possible to strengthen the projecting base material section 3 overall. Therefore, it is possible to enhance detection sensitivity and to easily fabricate with high yield rate.

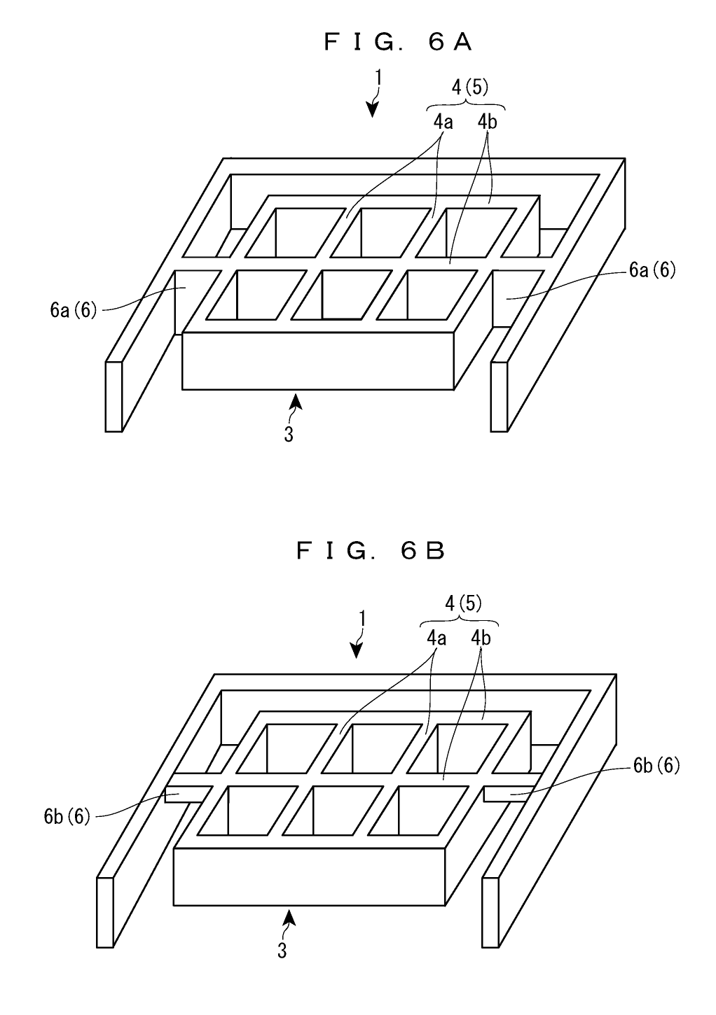

Referring to FIG. 6, a second embodiment of the infrared ray sensor will be explained. In this explanation, portions different from those of the first embodiment will be mainly explained. In an infrared ray sensor 1A according to the second embodiment, a projecting base material section 3A is disposed inside a frame-shaped substrate section 2 having space therebetween and is supported by the frame-shaped substrate section 2 via a beam section 6. In this case, the beam section 6 may be formed as a pair (plurality) of beam-like connection sections 6A, 6A as shown in FIG. 6A or as a pair (plurality) of bar-like connection sections 6A, 6A as shown in FIG. 6B provided between the projecting base material section 3A and the frame-shaped substrate section 2.

The pair of beam-like connection sections 6A, 6A in FIG. 6A are positioned on the centerline of the projecting base material section 3A in a plane and is formed in the identical formation with the above described element base material section 4, having an infrared ray detection section 5A. The infrared ray detection section 5A of the pair of beam-like connection sections 6A, 6A also serves as wiring for taking out a detection signal.

Likewise, the pair of bar-like connection sections 6B, 6B in FIG. 6B are positioned on the centerline of the projecting base material section 3A in a plane and is provided between upper end portions of the projection base material section 3A and the frame-shaped substrate section 2. Also in this case, the infrared ray detection section 5A is formed on each bar-like connection section 6B. Further, the infrared ray detection section 5A of the pair of bar-like connection sections 6B, 6B also serves as wiring for taking out the detection signal. In this case, the pair of bar-like connection sections 6B, 6B may be provided between lower end portions or intermediate portions of the projecting base material section 3A and the frame-shaped substrate section 2.

Note that the number and the formation of the connection sections making up the beam section 6 is arbitrary. For example, the beam section 6 may be made up a plurality of planar connection sections.

Cross sectional structures of each projecting base material section 3A and each infrared ray detection section 5A are the same as those of the first embodiment (see FIG. 2), and the explanations therefor are omitted. A method of fabricating the infrared ray sensor 1A includes the etching process by which the silicon substrate is penetrated (see FIG. 5A), the thermal oxidation process (see FIG. 5B) and the film formation process (see FIG. 5C) to fabricate the infrared ray sensor 1A.

With such a structure, since the projecting base material section 3A provided with the infrared ray detection section 5A elongates to the incident direction of the infrared ray, this portion can be easily formed by etching (penetration etching). Further, since the infrared ray detection section 5A is provided on the projecting base material section 3A overall, the infrared ray can be received sufficiently. Still further, since the projecting base material section 3A is formed smaller and is connected via the beam 6 to the frame-shaped substrate section 2, it is possible to restrain a heat transfer path of the projecting base material section 3A and heat transfer to the frame-shaped substrate section 2. Therefore, it is possible to enhance detection sensitivity and to easily fabricate with high yield rate.

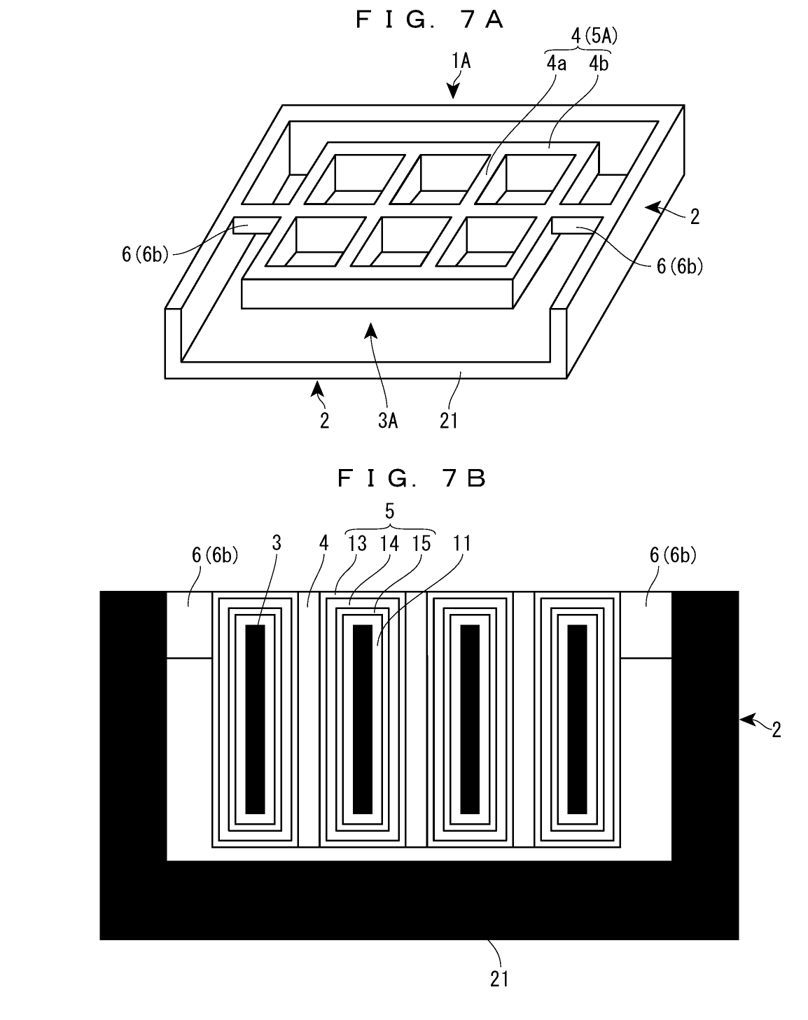

Referring to FIG. 7, a third embodiment of the infrared ray sensor will be explained. In the explanation, portions different from those of the second embodiment will be mainly explained. An infrared ray sensor 1B of the third embodiment has a projecting base material section 3B which is formed by truncating a bottom portion of the projecting base material section 3A in the second embodiment and is covered with a thin base substrate section 7 between bottom ends of the frame-shaped substrate section 2. Further, the projecting base material section 3B is supported on the frame-shaped substrate section 2 by the beam section 6 having a pair (plurality) of bar-like connection sections 6A, 6A as the second embodiment. Cross sectional structures of each projecting base material section 3B and each infrared ray detection section 5B are the same as those of the second embodiment (see FIG. 2), and the explanations therefor are omitted.

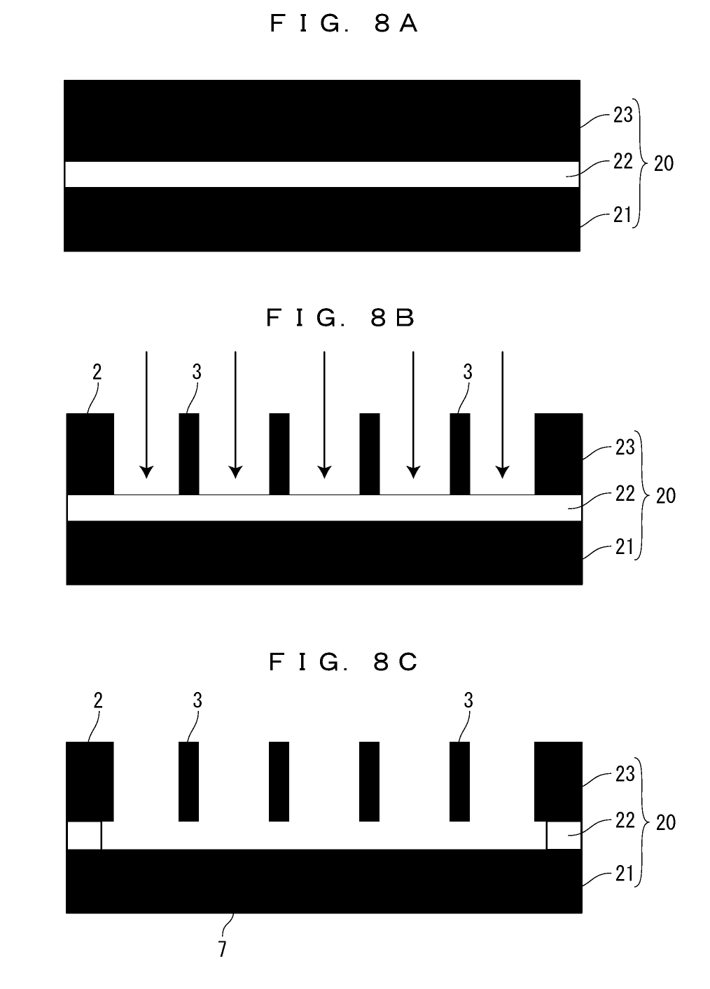

As shown in FIG. 8, in a method of fabricating the infrared ray sensor 1B of the third embodiment, a laminated substrate 20 is prepared, in which a bottom substrate 21 as the base substrate section 7, a sacrifice layer 22 which serves as space (gap) between the projecting base material section 3B and the base substrate section 7 and a top substrate 23 as the frame-shaped substrate section 2 are laminated (see FIG. 8A). The laminated substrate 20 is etched such that the top substrate 23 is penetrated so as to form the frame-shaped substrate section 2 and the projecting base material section 3B having the lattice shape (etching process: FIG. 8B). Next, the sacrifice layer of a trench portion (perforated portion) of the projecting base material section 3B is removed by etching (sacrifice layer etching process: FIG. 8C). Then, the thermal oxidation process (see FIG. 6B) and the film formation process (see FIG. 6C) are performed as the second embodiment. The gap portion between the frame-shaped substrate section 2 and the projecting base material section 3B may be removed by etching while a single plate substrate is used in place of the laminated substrate 20.

With this structure, since the projecting base material section 3B is formed smaller and is connected via the beam 6 to the frame-shaped substrate section 2, it is possible to restrain a heat transfer path of the projecting base material section 3B and heat transfer to the frame-shaped substrate section 2. Therefore, it is possible to enhance detection sensitivity and to easily fabricate with high yield rate.

Further, strength can be increased by providing the base substrate section 7. A reflective layer may be provided on a surface of the base substrate 7 to reflect an infrared ray reaching to the trench portion (perforated portion) toward the infrared ray detection section 5B.

In the embodiments above, though the pyroelectric-type infrared ray sensors have been explained, the present invention can be applied to infrared ray sensors such as a bolometer and a thermopile.

1-13. (canceled)

14. An infrared ray sensor making up one pixel in an infrared ray detection apparatus in an array format comprising:
a frame-shaped substrate section formed in a square frame shape;
a projecting base material section formed inside the frame-shaped substrate section and elongating to an upper and a lower directions to be an incident direction of an infrared ray;
an infrared ray detection section provided on at least an upper lateral surface of the projecting base material section; and
a beam section that supports the projecting base material section on the frame-shaped substrate section;
the projecting base material section being made up of a plurality of rib-like element base material sections combined in a net shape along an upper and a lower directions and being disposed inside the frame-shaped substrate section having space therebetween.

15. The infrared ray sensor according to claim 14, wherein the beam section is made up of a plurality of beam-like connection sections provided between the projecting base material section and the frame-shaped substrate section.

16. The infrared ray sensor according to claim 14, wherein the beam section is made up of a plurality of bar-like connection sections provided between the projecting base material section and the frame-shaped substrate section.

17. The infrared ray sensor according to claim 15 further having a base substrate section that covers between bottom ends of the frame-shaped substrate section and is provided spaced apart from the projecting based material section.

18. The infrared ray sensor according to claim 15, wherein the frame-shaped substrate section and the projecting base material section are formed integrally with same material.

19. The infrared ray sensor according to claim 15, wherein length size of the projecting base material section to an elongation direction is larger than thickness size thereof.

20. The infrared ray sensor according to claim 15, wherein the projecting base material section is formed with heat insulation material or has a heat insulation layer on a surface thereof.

21. The infrared ray sensor according to claim 15, wherein an infrared ray absorption layer is formed on a surface of the infrared ray detection section.

22. The infrared ray sensor according to claim 15, wherein the infrared ray detection section is laminated with an outer electrode layer, a pyroelectric layer and an inner electrode layer.

23. A method of fabricating the infrared ray sensor according to claim 14, comprising steps of:
etching by which a substrate is etched to pass through so as to form the frame-shaped substrate section and the projecting base material section in a net shape; and
film forming that film-forms the infrared ray detection section on the projecting base material section after the etching.

24. A method of fabricating the infrared ray sensor according to claim 17, comprising steps of:
preparing a laminated substrate that is laminated with a bottom substrate as the base substrate section, a sacrifice layer to be space between the projecting base material section and the base substrate section, and a top substrate as the frame-shaped substrate section;
etching the laminated substrate in which the top substrate is penetrated to form the frame-shaped substrate section and the projecting base material section in a net shape;
sacrifice layer etching to remove the sacrifice layer by etching after etching the laminated substrate; and
film-forming the infrared ray detection section on the projecting base material section after the sacrifice etching.
